(19) United States
(12) Patent Application Publication
(10) Pub. No.: US 2024/0006515 A1
(43) Pub. Date: Jan. 4, 2024

(54) SEMICONDUCTOR STRUCTURE AND FORMING METHOD THEREOF, AND PHOTOMASK LAYOUT

(71) Applicants: SEMICONDUCTOR MANUFACTURING INTERNATIONAL (SHANGHAI) CORPORATION, Shanghai (CN); SEMICONDUCTOR MANUFACTURING INTERNATIONAL (BEIJING) CORPORATION, Beijing (CN)

(72) Inventors: Kuchanari SUBHASH, Shanghai (CN); Jisong JIN, Shanghai (CN); Nalawar PRASANNA, Shanghai (CN); Jun WANG, Shanghai (CN)

(73) Assignees: SEMICONDUCTOR MANUFACTURING INTERNATIONAL (SHANGHAI) CORPORATION, Shanghai (CN); SEMICONDUCTOR MANUFACTURING INTERNATIONAL (BEIJING) CORPORATION, Beijing (CN)

(21) Appl. No.: 18/368,113

(22) Filed: Sep. 14, 2023

Related U.S. Application Data
(63) Continuation of application No. PCT/CN2021/081155, filed on Mar. 16, 2021.

(51) Int. Cl. H01L 29/66; H01L 27/092; H01L 29/78; H01L 21/8238

(52) U.S. Cl. CPC H01L 29/66795; H01L 27/0924; H01L 29/66545; H01L 29/7851; H01L 21/823821

(57) ABSTRACT

Provided are a semiconductor structure and a forming method thereof, and a photomask layout. One form of a semiconductor structure includes: a base, including a substrate and a plurality of fins arranged in parallel on the substrate, the substrate including a transistor cell area, and in the transistor cell area, in a direction perpendicular to an extending direction of the fin, the fin closest to a boundary of the transistor cell area being used as an edge fin, and the edge fin having an outer side wall facing the boundary of the transistor cell area; and a gate structure, spanning the fin and covering a part of a top and a part of a side wall of the fin, and the gate structure exposing at least a part of an outer side wall of any of the edge fins.

### RELATED APPLICATIONS

The present application is a continuation application of PCT Patent Application No. PCT/CN2021/081155, filed on Mar. 16, 2021, the entire content of which is incorporated herein by reference.

### TECHNICAL FIELD

Embodiments and implementations of the disclosure relate to the field of semiconductor manufacturing, in particular to a semiconductor structure and a forming method thereof, and a photomask layout.

### BACKGROUND

With the development of semiconductor technology, a semiconductor process node is decreasing following the development trend of the Moore's law. In order to adapt to this decrease in the process node, a channel length of MOSFETs has been reduced accordingly. However, with the reduction of the channel length, a distance between a source and drain of a device is also reduced, so the ability to control a gate on a channel becomes worse, and it is more and more difficult for the voltage of the gate to pinch off the channel, which makes the subthreshold leakage, i.e., the short-channel effects (SCEs), more likely to occur.

Therefore, in order to adapt to the scale-down of a size of the device, semiconductor processes have gradually begun to transition from planar MOSFETs to three-dimensional transistors with higher efficacy, such as fin field-effect transistors (FinFETs). In the FinFET, the gate can control an ultra-thin body (fin) from at least two sides, and the gate has stronger ability to control the channel and thus can well suppress the short-channel effects as compared with the planar MOSFETs. Compared with other devices, the FinFET has better compatibility with the existing manufacturing of integrated circuits.

### Technical Problem

The problem to be addressed by the embodiments of the disclosure is to provide a semiconductor structure and a forming method thereof, and a photomask layout to improve the flexibility to adjust an effective channel width.

### Technical Solutions

To address the above problem the disclosure provides a semiconductor structure. In one form, a semiconductor structure includes: a base, including a substrate and a plurality of fins arranged in parallel on the substrate, the substrate including a transistor cell area for forming transistors, and in the transistor cell area, in a direction perpendicular to an extending direction of the fin, the fin closest to a boundary of the transistor cell area is used as an edge fin, and the edge fin has an outer side wall facing the boundary of the transistor cell area; and a gate structure, located on the base and spanning the fin, the gate structure covering a part of a top and a part of a side wall of the fin, and the gate structure exposing at least a part of an outer side wall of any of the edge fins.

The disclosure further provides a forming method of a semiconductor structure. In one form, a method includes: providing a base, including a substrate and a plurality of fins arranged in parallel on the substrate, the substrate including a transistor cell area for forming transistors, and in the transistor cell area, in a direction perpendicular to an extending direction of the fin, the fin closest to a boundary of the transistor cell area being used as an edge fin, and the edge fin having an outer side wall facing the boundary of the transistor cell area; forming a gate structure spanning the fin on the base, the gate structure covering a part of a top and a part of a side wall of the fin; and etching the gate structure on an outer side wall of any of the edge fins to remove at least a part of the gate structure on the outer side wall.

The disclosure further provides a photomask layout. In one form, a photomask layout includes: an active area layout, including a transistor cell area for forming transistors, the transistor cell area having an active area pattern; a fin layout, including a plurality of fin patterns arranged in parallel in the active area pattern, and in a direction perpendicular to an extending direction of the fin pattern, the fin pattern closest to a boundary of the transistor cell area being used as an edge fin pattern, and the edge fin pattern having an outer boundary facing the boundary of the transistor cell area; a gate layout, including a gate pattern located in the cell area, the gate pattern spanning the fin pattern and being orthogonal to the fin pattern; and a gate cut layout, including a first gate cut pattern, the first gate cut pattern covering the gate pattern between any outer boundary and the boundary of the transistor cell area.

Beneficial Effects

Compared with the prior art, technical solutions of embodiments and implementations of the disclosure have at least the following advantages: in semiconductor structures provided by the disclosure, the substrate includes the transistor cell area for forming the transistors, and in the transistor cell area, in the direction perpendicular to the extending direction of the fin, the fin closest to the boundary of the transistor cell area is used as the edge fin, and the edge fin has the outer side wall facing the boundary of the transistor cell area; and the gate structure is located on the base and spans the fin, the gate structure covers a part of the top and a part of the side wall of the fin, and the gate structure exposes at least a part of the outer side wall of any of the edge fins. Both the side wall and the top of the fin can be used for providing channels of the transistor, that is, both a height and a width of the fin covered by the gate structure may affect an effective channel width of the transistor. Therefore, with at least a part of the outer side wall of any of the edge fins being exposed by the gate structure, an area of the side wall of the edge fin covered by the gate structure is reduced, so that the effective channel width of the fin can be reduced by adjusting a height of the outer side wall exposed by the gate structure while ensuring the normal operation of the transistor, thereby improving the flexibility to adjust the effective channel width of the transistor.

In one form of a forming method of a semiconductor structure provided by an embodiment of the disclosure, the substrate includes the transistor cell area for forming the transistors, and in the transistor cell area, in the direction perpendicular to the extending direction of the fin, the fin closest to the boundary of the transistor cell area is used as the edge fin, and the edge fin has the outer side wall facing the boundary of the transistor cell area; and after the gate structure spanning the fin is formed on the base, the gate structure on the outer side wall of any of the edge fins is etched to remove at least a part of the gate structure on the outer side wall. Both the side wall and the top of the fin can be used for providing channels of the transistor, that is, both the height and the width of the fin covered by the gate structure may affect the effective channel width of the transistor.

Therefore, by etching the gate structure on the outer side wall of any of the edge fins to remove at least a part of the gate structure on the outer side wall, the area of the side wall of the edge fin covered by the gate structure is reduced, so that the height of the outer side wall exposed by the gate structure can be adjusted by adjusting the etching amount of the gate structure on the outer side wall while ensuring the normal operation of the transistor, and the effective channel width of the fin is reduced accordingly, thereby improving the flexibility to adjust the effective channel width of the transistor.

In one form of a photomask layout provided by the disclosure, the fin layout includes the plurality of fin patterns arranged in parallel in the transistor cell area, and in the direction perpendicular to the extending direction of the fin pattern, the fin pattern closest to the boundary of the transistor cell area is used as the edge fin pattern, and the edge fin pattern has the outer boundary facing the boundary of the transistor cell area; the gate layout includes the gate pattern located in the cell area, and the gate pattern spans the fin pattern and is orthogonal to the fin pattern; and the photomask layout includes the gate cut layout, the gate cut layout includes the first gate cut pattern, and the first gate cut pattern covers the gate pattern between any outer boundary and the boundary of the transistor cell area.

The fin pattern is used for forming the fin, the edge fin pattern is accordingly used for forming the edge fin, the gate pattern is used for forming the gate structure, and the first gate cut pattern is used for defining the etched area in the gate structure. Therefore, by adding the first gate cut pattern in the photomask layout, when the semiconductor structure is formed by using the photomask layout, the gate structure on the outer side wall of any of the edge fins can be etched to remove at least a part of the gate structure on the outer side wall.

Both the side wall and the top of the fin can be used for providing channels of the transistor, that is, both the height and the width of the fin covered by the gate structure may affect the effective channel width of the transistor. Accordingly, by etching the gate structure on the outer side wall of any of the edge fins to remove at least a part of the gate structure on the outer side wall, the area of the side wall of the edge fin covered by the gate structure is reduced, so that the height of the outer side wall exposed by the gate structure can be adjusted by adjusting the etching amount of the gate structure on the outer side wall while ensuring the normal operation of the transistor, and the effective channel width of the fin is reduced accordingly, thereby improving the flexibility to adjust the effective channel width of the transistor.

### BRIEF DESCRIPTION OF THE DRAWINGS

FIG. 1 is a schematic structural diagram of a semiconductor structure;

FIG. 2 is a schematic structural diagram of one form of a semiconductor structure according to the disclosure.

FIG. 3 is a schematic structural diagram of another form of a semiconductor structure according to the disclosure.

FIG. 4 is a schematic structural diagram of yet another form of a semiconductor structure according to the disclosure.

FIG. 5 to FIG. 7 are schematic structural diagrams corresponding to steps of one form of a forming method of a semiconductor structure according to the disclosure.

FIG. 8 to FIG. 9 are schematic structural diagrams corresponding to steps of another form of a forming method of a semiconductor structure according to the disclosure.

FIG. 10 is a schematic structural diagram of yet another form of a forming method of a semiconductor structure according to the disclosure.

FIG. 11 is a schematic diagram of one form of a photomask layout according to the disclosure.

### DETAILED DESCRIPTION

At present, it is difficult to adjust an effective channel width of a transistor. The reasons why it is difficult to adjust the effective channel width of the transistor will be analyzed in conjunction with the accompanying drawings.

Referring to FIG. 1, a schematic structural diagram of a semiconductor structure is shown.

The semiconductor structure includes: a substrate 10; a fin 11, convexly disposed on the substrate 10; an isolation layer 12, located on the substrate 10 exposed by the fin 11 and covering a part of a side wall of the fin 11; and a gate structure 20, located on the isolation layer 12 and spanning the fin 11, the gate structure 20 covering a part of a top and a part of the side wall of the fin 11. Both a height and a width of the fin 11 covered by the gate structure 20 may affect the effective channel width of the transistor. Specifically, when the gate structure 20 covers the top and the two opposite side walls of the fin 11, the effective channel width that can be provided by a single fin 11 is the sum of the width of the fin 11 and twice the effective height of the fin 11.

It should be noted that the effective height of the fin 11 refers to the height of the fin 11 exposed by the isolation layer 12.

In an existing FinFET structure, the effective channel width that can be provided by the single fin is fixed (i.e., the sum of the width of the fin and twice the effective height of the fin) and unchangeable, and the effective channel width of the transistor can be changed only by changing the number of the fins corresponding to the transistor (e.g., as shown in FIG. 1, the number of the fins 11 corresponding to the transistor is five), so that the effective channel width can only be increased by a positive integer multiple, making it difficult to freely adjust the effective channel width of the transistor according to the performance requirements (e.g., saturation current) of the transistor. Similarly, for a standard cell, the number of fins in the standard cell is changed to control leakage current and firing current to adapt to appropriate applications, but the effective channel width can still be increased only by a positive integer multiple. In addition, when the number of tracks of the standard cells is further reduced from 6 (6T), since the number of the fins in each active area in the 6T standard cell is two, it is difficult to further reduce the height of the standard cell. Besides, the number of the fins can only be reduced from two to one, so the process flexibility is low. Moreover, when the number of the fins in each active area is reduced to one, the driving current is likely to be too small.

To address the technical problems, the disclosure provides a semiconductor structure. In one form, a semiconductor structure includes: a base, including a substrate and a plurality of fins arranged in parallel on the substrate, the substrate including a transistor cell area for forming transistors, and in the transistor cell area, in a direction perpendicular to an extending direction of the fin, the fin closest to a boundary of the transistor cell area being used as an edge fin, and the edge fin having an outer side wall facing the boundary of the transistor cell area; and a gate structure, located on the base and spanning the fin, the gate structure covering a part of a top and a part of a side wall of the fin, and the gate structure exposing at least a part of an outer side wall of any of the edge fins.

In some implementations, both the side wall and the top of the fin can be used for providing channels of the transistor, that is, both a height and a width of the fin covered by the gate structure may affect the effective channel width of the transistor. Therefore, by making the gate structure exposes at least a part of the outer side wall of any of the edge fins, the area of the side wall of the edge fin covered by the gate structure is reduced, so that the effective channel width of the fin can be reduced by adjusting the height of the outer side wall exposed by the gate structure while ensuring the normal operation of the transistor, thereby improving the flexibility to adjust the effective channel width of the transistor.

To make the foregoing objectives, features, and advantages of embodiments and implementations of the disclosure more apparent and easier to understand, specific embodiments and implementations of the disclosure are described in detail below with reference to the accompanying drawings.

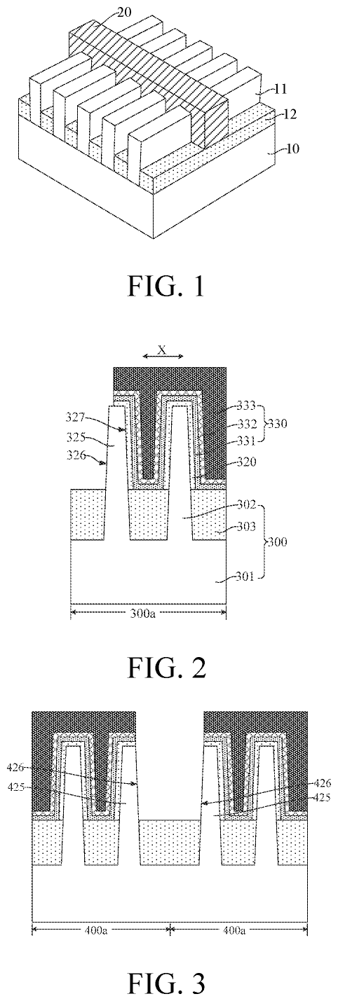

FIG. 2 is a schematic structural diagram of one form of a semiconductor structure according the disclosure.

The semiconductor structure includes: a base 300, including a substrate 301 and a plurality of fins 302 arranged in parallel on the substrate 301, the substrate 301 including a transistor cell area 300a for forming transistors, and in the transistor cell area 300a, in a direction perpendicular to an extending direction of the fin 302, the fin 302 closest to a boundary of the transistor cell area 300a being used as an edge fin 325, and the edge fin 325 having an outer side wall 326 facing the boundary of the transistor cell area 300a; and a gate structure 330, located on the base 300 and spanning the fin 302, the gate structure 330 covering a part of a top and a part of a side wall of the fin 302, and the gate structure 330 exposing at least a part of an outer side wall 326 of any of the edge fins 325.

Both the side wall and the top of the fin 302 can be used for providing channels of the transistor, that is, both a height and a width of the fin 302 covered by the gate structure 330 may affect an effective channel width of the transistor. When the gate structure 330 covers the fin 302, the effective channel width that can be provided by one fin 302 is the sum of the width of the fin 302 and twice the effective height of the fin 302. Therefore, with at least a part of the outer side wall 326 of any of the edge fins 325 being exposed by the gate structure 330, the area of the side wall of the edge fin 325 covered by the gate structure 330 is reduced, so that the effective channel width of the fin 302 can be reduced by adjusting a height of the outer side wall 326 exposed by the gate structure 330 while ensuring the normal operation of the transistor, thereby improving the flexibility to adjust the effective channel width of the transistor. The width of the fin 302 refers to a dimension of the fin 302 in the direction parallel to a surface of the substrate 301 and perpendicular to the extending direction of the fin 302. The semiconductor structure typically further includes an isolation layer 303 located on the substrate 301 and covering a part of the side wall of the fin 302. The effective height of the fin 302 refers to the height of the fin 302 exposed by the isolation layer.

Specifically, solutions provided by this implementation can break through the current limitation that the effective channel width of the transistor can be changed only by changing the number of fins corresponding to the transistor, i.e., the limitation that the effective channel width can be increased only by a positive integer multiple. Moreover, in the transistor cell area 300a, when the number of the fins 302 corresponding to each transistor is two, compared with the solution in which only one fin is used, with at least a part of the outer side wall 326 of any of the edge fins 325 being exposed by the gate structure 330, the effective channel width of the transistor can be reduced, and the problem of too small driving current can be improved. Besides, with at least a part of the outer side wall 326 of any of the edge fins 325 being exposed by the gate structure 330, more design options can be provided for the standard cell to adapt to more application demands. For example, the number of tracks of the standard cell can be further reduced from 6 (6T) to further reduce a height of the standard cell.

In this implementation, the semiconductor structure is a fin field-effect transistor, and accordingly, the base 300 includes a substrate 301 and a plurality of fins 302 arranged in parallel on the substrate 301. In this implementation, a material of the substrate 301 is silicon. In some other implementations, a material of the substrate may also be another material such as germanium, silicon-germanium, silicon carbide, gallium arsenide, indium-gallium or the like. The substrate may also be another type of substrate such as a silicon on insulator substrate, a germanium on insulator substrate or the like.

The fins 302 are separately disposed on the substrate 301, and a part of the height of the fin 302 is used for providing a channel of the fin field-effect transistor. In this implementation, the fin 302 and the substrate 301 form an integrated structure, and a material of the fin 302 is the same as the material of the substrate 301, i.e., silicon. In some other implementations, the material of the fin may also be germanium, silicon-germanium, silicon carbide, gallium arsenide or indium-gallium. In other implementations, according to actual conditions, the fin may also be a semiconductor layer epitaxially grown on the substrate, and the materials of the fin and the substrate may also be different.

In this implementation, in the direction perpendicular to the extending direction of the fin 302, the edge fin 325 has the outer side wall 326 facing the boundary of the transistor cell area 300a, and the edge fin 325 also has an inner side wall 327 opposite to the outer side wall 326.

In this implementation, the substrate 301 includes the transistor cell area 300a for forming the transistors. The transistors in each transistor cell area 300a share a gate structure 330. It should be noted that each transistor cell area 300a is not limited to forming transistors of the same channel conductivity type. For example, one transistor cell area 300a can be used for forming an NMOS transistor and a PMOS transistor, i.e., one transistor cell area 300a can be used for forming a plurality of transistors, and the NMOS transistor and the PMOS transistor share a gate structure 330. In other implementations, according to the circuit design, each transistor cell area is only used for forming transistors of the same channel conductivity type (NMOS transistors or PMOS transistors), and each transistor cell area is used for forming only one transistor.

In this implementation, the fin 302 closest to the boundary of the transistor cell area 300a is used as the edge fin 325. In the direction perpendicular to the extending direction of the fin 302, the transistor cell area 300a has two boundaries, so the number of the edge fins 325 is two accordingly. In this implementation, in the transistor cell area 300a, in the direction perpendicular to the extending direction of the fin 302, the number of the fins 302 is plural. Specifically, the number of the fins 302 in the transistor cell area 300a is set according to the performance requirements of the transistor. The gate structure 330 spans the fin 302 and covers a part of the top and a part of the side wall of the fin 302, so both the side wall and the top of the fin 302 can provide the channels of the transistor. The larger the number of the fins 302, the larger the effective channel width of the transistor. As an example, the number of the fins 302 is two. Accordingly, the two fins 302 can both used as the edge fins 325. In some other implementations, for example, when the number of the fins is five, the number of the edge fins is two, and the number of the remaining fins located between the edge fins is three.

In other implementations, according to actual demands, in the direction perpendicular to the extending direction of the fin, the fin close to one boundary of the transistor cell area is used as the edge fin, i.e., the number of the edge fins may also be one.

In this implementation, in the direction perpendicular to the extending direction of the fin 302, a top width of the fin 302 is greater than a bottom width of the fin 302, i.e., a section of the fin 302 is in the shape of a trapezoid.

In this implementation, the base 300 further includes: an isolation layer 303, located on the substrate 301 exposed by the fin 302, the isolation layer 303 covering a part of the side wall of the fin 302. The isolation layer 303, serving as a shallow trench isolation (STI) structure, is used for isolating adjacent devices. Besides, the isolation layer 303 is used for defining the effective height of the fin 302, that is, the fin 302 exposed from the isolation layer 303 is used for providing the channel of the transistor. A material of the isolation layer 303 is an insulating material. As an example, the material of the isolation layer 303 is silicon oxide. In other implementations, the material of the isolation layer may also be silicon nitride, silicon oxynitride or silicon oxycarbonitride.

In this implementation, the gate structure 330 is a device gate structure. The device gate structure is used for controlling the turn-on and turn-off of the channel of the transistor. As an example, the gate structure 330 is a metal gate (MG). Specifically, the metal gate includes a gate dielectric layer 331 conformally covering the top and the side wall of the fin 302, a work function layer 332 conformally covering the gate dielectric layer 331, and a gate electrode layer 333 conformally covering the work function layer 332.

In this implementation, the gate dielectric layer 331 is a high k gate dielectric layer, and a material of the gate dielectric layer 331 is a high k dielectric material. The high k dielectric material refers to a dielectric material having a relative dielectric constant greater than a relative dielectric constant of silicon oxide. Specifically, the material of the gate dielectric layer 331 may be selected from HfO₂, ZrO₂, HfSiO, HfSiON, HfTaO, HfTiO, HfZrO, Al₂O₃ or the like. As an example, the material of the gate dielectric layer 331 is HfO₂.

The work function layer 332 is used for adjusting a threshold voltage of the fin field-effect transistor. When the device is a PMOS transistor, the work function layer 332 is a P-type work function layer, and a material of the P-type work function layer includes one or more of TiN, TaN, TaSiN, TaAlN and TiAlN. When the device is an NMOS transistor, the work function layer 332 is an N-type work function layer, and a material of the N-type work function layer includes one or more of TiAl, Mo, MoN, AlN and TiAlC.

The gate electrode layer 333 is a metal gate layer used for electrically leading out the metal gate. A material of the gate electrode layer 333 includes one or more of TiN, TaN, Ta, Ti, TiAl, W, Al, TiSiN and TiAlC. As an example, the material of the gate electrode layer 333 is W.

By adjusting the height of the outer side wall 326 exposed by the gate structure 330, the effective channel width of the fin 302 is adjusted (specifically, the effective channel width of the fin 302 is reduced), thereby improving the flexibility to adjust the effective channel width of the transistor. It should be noted that the transistors located in the same transistor cell area 300a share a gate structure 330, so in the same transistor cell area 300a, it is not possible to separate the gate structure 330 between adjacent fins 302, and it is only possible to make the gate structure 330 expose at least a part of the outer side wall 326 of any of the edge fins 325 to ensure the completeness of the gate structure 330 in the same transistor cell area 300a and correspondingly to ensure the normal operation of the transistor.

In this implementation, according to the performance requirements and circuit design of the transistor, the gate structure 330 may be made to expose only a part of the outer side wall 326 or the entire outer side wall 326 of one edge fin 325, or the gate structure 330 may also be made to expose a part of the outer side wall 326 or the entire outer side wall 326 of two edge fins 125. As shown in FIG. 3, as an example, the gate structure 330 exposes only the outer side wall 326 of one edge fin 325.

In this implementation, according to the performance requirements of the transistor, the gate structure 330 exposes a part of the outer side wall 326 of any of the edge fins 325; or the gate structure 330 exposes the entire outer side wall 326 of any of the edge fins 325; or the gate structure 330 exposes the entire outer side wall 326 of any of the edge fins 325 and also exposes a part of a top of the edge fin 325; or the gate structure 330 exposes the entire outer side wall 326 of any of the edge fins 325 and also exposes the top of the edge fin 325. During the formation of the semiconductor structure, the gate structure 330 is typically etched to make the gate structure 330 expose the outer side wall 326. In the direction perpendicular to the extending direction of the fin 302, the top width of the fin 302 is greater than the bottom width of the fin 302, so it is technically easy to make the gate structure 330 expose a part of the outer side wall 326 of the edge fin 125.

As an example, the gate structure 330 exposes the entire outer side wall 326 of any of the edge fins 325 and also exposes a part of the top of the edge fin 325. With a part of the top of the edge fin 325 being also exposed by the gate structure 330, during the formation of the semiconductor structure, it is beneficial to increase the process window for etching the gate structure 330 and lower the requirements for alignment accuracy in a photo-lithography process, and the edge fin 325 is still covered with sufficient gate structure 330, which is beneficial to ensure the ability of the gate structure 330 to control the channel in the edge fin 325.

It should be noted that the edge fin 325 also has the inner side wall 327 opposite to the outer side wall 326, and the gate structure 330 covers the inner side wall 327 of the edge fin 325 to ensure the normal performance of the transistor.

In this implementation, the semiconductor structure further includes: a gate oxide layer 320, located between the gate structure 330 and the fin 302. In other implementations, the gate oxide layer may also extend to cover the outer side wall exposed by the gate structure. During the formation of the semiconductor structure, when etching the gate structure 330, the gate oxide layer 320 on a surface of the edge fin 325 can be used as an etch stop layer, thereby reducing the damage to the fin 302 caused by the process of etching the gate structure 330. Besides, for devices with higher operating voltage (for example, input/output devices), the gate oxide layer 320 is also used for isolating the gate structure 330 and the channel. A material of the gate oxide layer 320 includes one or both of silicon oxide and silicon oxynitride. As an example, the material of the gate oxide layer 320 is silicon oxide.

It should be noted that the semiconductor structure further includes: an interlayer dielectric layer (not shown), located on the base 300 on a side of the gate structure 330 and covering the side wall of the gate structure 330, the interlayer dielectric layer also covering the edge fin 325 exposed by the gate structure 330. The interlayer dielectric layer is used for isolating adjacent devices. A material of the interlayer dielectric layer is an insulating material. As an example, the material of the interlayer dielectric layer is silicon oxide.

FIG. 3 is a schematic structural diagram of another form of a semiconductor structure according to the disclosure.

The similarities between this implementation of the disclosure and the foregoing implementations are not repeated here, and this implementation of the disclosure differs from the foregoing implementations primarily in that: the number of the transistor cell areas 400a is plural.

In this implementation, the transistors in each transistor cell area 400a share a gate structure, and the gate structures (not shown) in adjacent transistor cell areas 400a are isolated. In this implementation, in the transistor cell area 400a, the fin closest to a junction of the adjacent transistor cell areas 400a is used as an edge fin 425. That is, the gate structure exposes an outer side wall 426 close to the junction of the adjacent transistor cell areas 400a.

Specifically, during the formation of the semiconductor structure, gate cut is typically performed on the gate structure at the junction of the adjacent transistor cell areas 400a to divide the gate structure of the adjacent transistor cell areas 400a in the extending direction of the gate structure. With the outer side wall 426 close to the junction of the adjacent transistor cell areas 400a being exposed by the gate structure, it is possible to etch the gate structure on the edge fin 425 and perform gate cut on the gate structure at the junction of the adjacent transistor cell areas 400a in one step, which thereby avoids introducing additional process steps; and moreover, it is possible to use one mask, which avoids additional masks.

For the detailed description of the semiconductor structure, reference may be made to the corresponding description in the foregoing implementation, as details will not be repeated here.

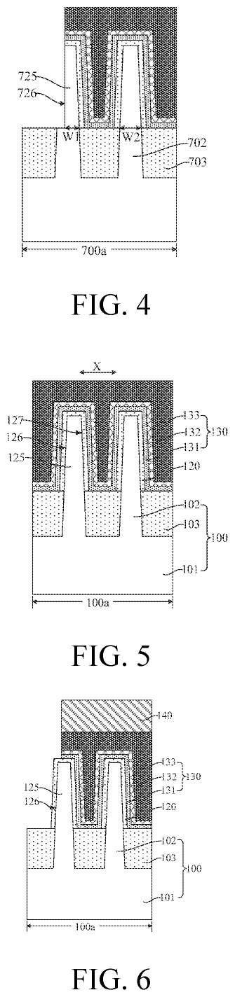

FIG. 4 is a schematic structural diagram of a semiconductor structure according to still another embodiment of the disclosure.

The similarities between this implementation of the disclosure and the foregoing embodiment are not repeated here, and this implementation of the disclosure differs from the foregoing embodiment in that: in a transistor cell area 700a, in the direction perpendicular to the extending direction of a fin 702, on a top surface of an isolation layer 703, an edge fin 725 corresponding to an outer side wall 726 exposed by the gate structure (not shown) has a first bottom width W1, and the remaining fin 702 has a second bottom width W2; and the first bottom width W1 is less than the second bottom width W2.

The gate structure exposes at least a part of the outer side wall 726. Therefore, by making the first bottom width W1 less than the second bottom width W2, compared with the other fins 702, the edge fin 725 corresponding to the outer side wall 726 exposed by the gate structure has a smaller width, thereby improving the ability of the gate structure to control the channel in the edge fin 725 and reducing the leakage current.

For the detailed description of the semiconductor structure, reference may be made to the corresponding description in the foregoing implementations, as details will not be repeated here.

FIG. 5 to FIG. 7 are schematic structural diagrams corresponding to steps of one form of a forming method of a semiconductor structure according to the disclosure.

Referring to FIG. 5, a base 100 is provided. The base includes a substrate 101 and a plurality of fins 102 arranged in parallel on the substrate 101. The substrate 101 includes a transistor cell area 100a for forming transistors, and in the transistor cell area 100a, in a direction perpendicular to an extending direction of the fin 102 (X-direction in FIG. 5), the fin 102 closest to a boundary of the transistor cell area 100a is used as an edge fin 125, and the edge fin 125 has an outer side wall 126 facing the boundary of the transistor cell area 100a.

The base 100 provides a technical operation basis for the forming process of the semiconductor structure. In this implementation, the semiconductor structure is a fin field-effect transistor, and accordingly, the base 100 includes a substrate 101 and a plurality of fins 102 arranged in parallel on the substrate 101. In this implementation, a material of the substrate 101 is silicon. In some other implementations, a material of the substrate may also be another material such as germanium, silicon-germanium, silicon carbide, gallium arsenide, indium-gallium or the like. The substrate may also be another type of substrate such as a silicon on insulator substrate, a germanium on insulator substrate or the like.

The fins 102 are separately disposed on the substrate 101, and a part of the height of the fin 102 is used for providing a channel of the fin field-effect transistor. In this implementation, the fins 102 and the substrate 101 form an integrated structure, and a material of the fins 102 is the same as the material of the substrate 101, i.e., silicon. In some other implementations, the material of the fin may also be germanium, silicon-germanium, silicon carbide, gallium arsenide or indium-gallium. In other implementations, according to actual conditions, the fin may also be a semiconductor layer epitaxially grown on the substrate, and the materials of the fin and the substrate may also be different.

In this implementation, in the direction perpendicular to the extending direction of the fin 102, the edge fin 125 has the outer side wall 126 facing the boundary of the transistor cell area 100a, and the edge fin 125 also has an inner side wall 127 opposite to the outer side wall 126.

In this implementation, the substrate 101 includes the transistor cell area 100a for forming the transistors. The transistors in each transistor cell area 100a share a gate structure. It should be noted that each transistor cell area 100a is not limited to forming transistors of the same channel conductivity type. For example, one transistor cell area 100a can be used for forming an NMOS transistor and a PMOS transistor, i.e., one transistor cell area 100a can be used for forming a plurality of transistors, and the NMOS transistor and the PMOS transistor share a gate structure. In other implementations, according to the circuit design, each transistor cell area is used for forming transistors of the same channel conductivity type, and each transistor cell area is used for forming only one transistor.

In this implementation, the fin 102 closest to the boundary of the transistor cell area 100a is used as the edge fin 125. In the direction perpendicular to the extending direction of the fin 102, the transistor cell area 100a has two boundaries, so the number of the edge fins 125 is two accordingly. In this implementation, in the transistor cell area 100a, in the direction perpendicular to the extending direction of the fin 102, the number of the fins 102 is plural. Specifically, the number of the fins 102 in the transistor cell area 100a is set according to the performance requirements of the transistor. The gate structure spans the fin 102 and covers a part of the top and a part of the side wall of the fin 102, so both the side wall and the top of the fin 102 can provide the channels of the transistor. The larger the number of the fins 102, the larger the effective channel width of the transistor. As an example, the number of the fins 102 is two. Accordingly, the two fins 102 can both used as the edge fins 125. In other implementations, for example, when the number of the fins is five, the number of the edge fins is two, and the number of the remaining fins located between the edge fins is three.

In other implementations, according to actual demands, in the direction perpendicular to the extending direction of the fin, the fin close to one boundary of the transistor cell area is used as the edge fin, i.e., the number of the edge fins may also be one.

In this implementation, in the direction perpendicular to the extending direction of the fin 102, a top width of the fin 102 is greater than a bottom width of the fin 102, i.e., a section of the fin 102 is in the shape of a trapezoid.

In this implementation, the base 100 further includes: an isolation layer 103, located on the substrate 101 exposed by the fin 102, the isolation layer 103 covering a part of the side wall of the fin 102. The isolation layer 103, serving as a shallow trench isolation (STI) structure, is used for isolating adjacent devices. Besides, the isolation layer 103 is used for defining the effective height of the fin 102, that is, the fin 102 exposed from the isolation layer 103 is an effective fin used for providing the channel of the transistor. A material of the isolation layer 103 is an insulating material. As an example, the material of the isolation layer 103 is silicon oxide. In other implementations, the material of the isolation layer may also be silicon nitride, silicon oxynitride or silicon oxycarbonitride.

Still referring to FIG. 5, a gate structure 130 spanning the fin 102 is formed on the base 100. The gate structure 130 covers a part of a top and a part of a side wall of the fin 102.

The gate structure 130 may include a device gate structure or a dummy gate. The device gate structure is used for controlling the turn-on and turn-off of the channel of the transistor. The dummy gate is used for occupying a space position for the subsequent formation of the device gate structure. In this implementation, when the gate structure 130 is the dummy gate, the dummy gate includes a polysilicon gate structure or an amorphous silicon gate structure. When the gate structure 130 is the device gate structure, the device gate structure includes a metal gate. As an example, the gate structure 130 is the metal gate. Specifically, the metal gate includes a gate dielectric layer 131 conformally covering the top and the side wall of the fin 102, a work function layer 132 conformally covering the gate dielectric layer 131, and a gate electrode layer 133 conformally covering the work function layer 132.

In this implementation, the gate dielectric layer 131 is a high k gate dielectric layer, and a material of the gate dielectric layer 131 is a high k dielectric material. Specifically, the material of the gate dielectric layer 131 may be selected from HfO₂, ZrO₂, HfSiO, HfSiON, HfTaO, HfTiO, HfZrO, Al₂O₃ or the like. As an example, the material of the gate dielectric layer 131 is HfO₂. The work function layer 132 is used for adjusting a threshold voltage of the fin field-effect transistor. When the device is a PMOS transistor, the work function layer 132 is a P-type work function layer, and a material of the P-type work function layer includes one or more of TiN, TaN, TaSiN, TaAlN and TiAlN. When the device is an NMOS transistor, the work function layer 132 is an N-type work function layer, and a material of the N-type work function layer includes one or more of TiAl, Mo, MoN, AlN and TiAlC. The gate electrode layer 133 is a metal gate layer used for electrically leading out the metal gate. A material of the gate electrode layer 133 includes one or more of TiN, TaN, Ta, Ti, TiAl, W, Al, TiSiN and TiAlC. As an example, the material of the gate electrode layer 133 is W.

It should be noted that before forming the metal gate, a first interlayer dielectric layer (not shown) is formed on the base 100. A gate opening (not shown) is formed in the first interlayer dielectric layer. The gate opening spans the fin 102 and exposes a part of the top and a part of the side wall of the fin 102. The gate opening is formed by removing the dummy gate, and accordingly, the metal gate is formed in the gate opening. In other implementations, when the gate structure is the dummy gate, after forming the gate structure, the method further includes: a first interlayer dielectric layer is formed on the base on a side of the gate structure. The first interlayer dielectric layer covers a side wall of the dummy gate and exposes a top of the dummy gate. The first interlayer dielectric layer is used for isolating adjacent devices. A material of the first interlayer dielectric layer is an insulating material. As an example, the material of first interlayer dielectric layer is silicon oxide.

In this implementation, before forming the gate structure 130, the forming method further includes: a gate oxide layer 120 is formed on the top and the side wall of the fin 102. Accordingly, in the step of forming the gate structure 130, the gate structure 130 covers the gate oxide layer 120, that is, the gate oxide layer 120 is also formed between the gate structure 130 and the fin 102. When etching the gate structure 130 subsequently, the gate oxide layer 120 can be used as an etch stop layer, thereby reducing the damage to the fin 102 caused by the process of etching the gate structure 130. Besides, for devices with higher operating voltage (for example, input/output devices), the gate oxide layer 120 is also used for isolating the gate structure and the channel. A material of the gate oxide layer 120 includes one or both of silicon oxide and silicon oxynitride. As an example, the material of the gate oxide layer 120 is silicon oxide.

Referring to FIG. 6, the gate structure 130 on the outer side wall 126 of any of the edge fins 125 is etched to remove at least a part of the gate structure 130 on the outer side wall 126.

Both the side wall and the top of the fin 102 can be used for providing channels of the transistor, that is, both the height and the width of the fin 102 covered by the gate structure 130 may affect the effective channel width of the transistor. When the gate structure 130 covers the fin 102, the channel width that can be provided by one fin 102 is the sum of the width of the fin 102 and twice the effective height of the fin 102. Therefore, by etching the gate structure 130 on the outer side wall 126 of any of the edge fins 125 to remove at least a part of the gate structure 130 on the outer side wall 126, an area of the side wall of the edge fin 125 covered by the gate structure 130 is reduced, so that the height of the outer side wall 126 exposed by the gate structure 130 can be adjusted by adjusting the etching amount of the gate structure 130 on the outer side wall 126 while ensuring the normal operation of the transistor, and the effective channel width of the fin 102 is reduced accordingly, thereby improving the flexibility to adjust the effective channel width of the transistor. The width of the fin 102 refers to a dimension of the fin 102 in the direction parallel to the surface of the substrate 101 and perpendicular to the extending direction of the fin 102. The effective height of the fin 102 refers to the height of the fin 102 exposed by the isolation layer 103.

Specifically, the solutions provided by this implementation can break through the current limitation that the effective channel width of the transistor can be changed only by changing the number of fins corresponding to the transistor, i.e., the limitation that the effective channel width can be increased only by a positive integer multiple. Moreover, in the transistor cell area 100a, when the number of the fins 102 corresponding to each transistor is two, compared with the solution in which only one fin is used, with at least a part of the outer side wall 126 being exposed by the gate structure 130, the effective channel width of the transistor can be reduced, and the problem of too small driving current can be improved. Besides, with at least a part of the outer side wall 126 being exposed by the gate structure 130, more design options can be provided for the standard cell to adapt to more application demands. For example, the number of tracks of the standard cell can be further reduced from 6 (6T) to further reduce a height of the standard cell.

It should be noted that the transistors located in the same transistor cell area 100a share a gate structure 130, so in the same transistor cell area 100a, it is not possible to etch the gate structure 130 between adjacent fins 102, and it is only possible to etch the gate structure 130 on the edge fin 125; and the gate structure 130 on the outer side wall 126 is etched first to ensure the completeness of the remaining gate structure 130 in the same transistor cell area 100a and correspondingly ensure the normal operation of the transistor.

According to the performance requirements and circuit design of the transistor, the gate structure 130 on the outer side wall 126 of only one edge fin 125 may be etched, or the gate structure 130 on the outer side walls 126 of two edge fins 125 may be etched. As shown in FIG. 6, as an example, the gate structure 130 on only one edge fin 125 is etched.

In this implementation, according to the performance requirements of the transistor, in the step of etching the gate structure 130 on the outer side wall 126 of any of the edge fins 125, a part of the gate structure 130 on the outer side wall 126 may be removed; or the gate structure 130 on the entire outer side wall 126 is removed; or the gate structure 130 on the entire outer side wall 126 is removed, and a part of the gate structure 130 on a top of the edge fin 125 is also removed; or the gate structure 130 on the entire outer side wall 126 is removed, and the gate structure 130 on the top of the edge fin 125 is also removed. The more the gate structure 130 on the edge fin 125 is removed, the smaller the channel width that the edge fin 125 can provide.

It should be noted that the edge fin 125 also has an inner side wall 127 opposite to the outer side wall 126, and after the gate structure 130 on the outer side wall 126 of any of the edge fins 125 is etched, the remaining gate structure 130 covers the inner side wall 127 of the edge fin 125 to ensure the normal performance of the transistor. It should also be noted that, in the direction perpendicular to the extending direction of the fin 102, a top width of the fin 102 is greater than a bottom width of the fin 102, so it is technically easy to remove the gate structure 130 on a part of the outer side wall 126.

As an example, the gate structure 130 on the entire outer side wall 126 is removed, and a part of the gate structure 130 on the top of the edge fin 125 is also removed, thereby increasing the process window for etching the gate structure 130 and lowering the requirements for alignment accuracy in the photo-lithography process; and the edge fin 125 is still covered with sufficient gate structure 130, which is beneficial to ensure the ability of the gate structure 130 to control the channel in the edge fin 125.

Specifically, the step of etching the gate structure 130 on the outer side wall 126 of any of the edge fins 125 includes: forming a mask layer 140 on tops of the base 100 and the gate structure 130, the mask layer 140 exposing the gate structure 130 on the outer side wall 126 of any of the edge fins 125; and by using the mask layer 140 as a mask, etching the gate structure 130 exposed by the mask layer 140. Accordingly, when the gate structure 130 on the entire outer side wall 126 is removed and a part of the gate structure 130 on the top of the edge fin 125 is also removed, the mask layer 140 also exposes the gate structure 130 on a part of the top of the edge fin 125. A mask opening in the mask layer 140 is large in size, and the process window for forming the mask opening is large.

A material of the mask layer 140 is a material that can be used as an etching mask, i.e., there is an etch selectivity between the gate structure 130 and the mask layer 140. The material of the mask layer 140 may be a hard mask material or a photo-resist. Specifically, the hard mask material is a dielectric material, for example, silicon nitride or the like.

In this implementation, the gate structure 130 on the outer side wall 126 of any of the edge fins 125 is etched by anisotropic dry etching. The anisotropic dry etching has the characteristics of anisotropic etching, which is beneficial to improve the etching controllability and improve the morphological quality of the etch profile of the remaining gate structure 130 after etching.

Specifically, in the step of etching the gate structure 130, the gate oxide layer 120 is used as an etch stop layer, thereby reducing the damage to the fin 102. Typically, there is a high etch selectivity between the gate structure 130 and the gate oxide layer 120.

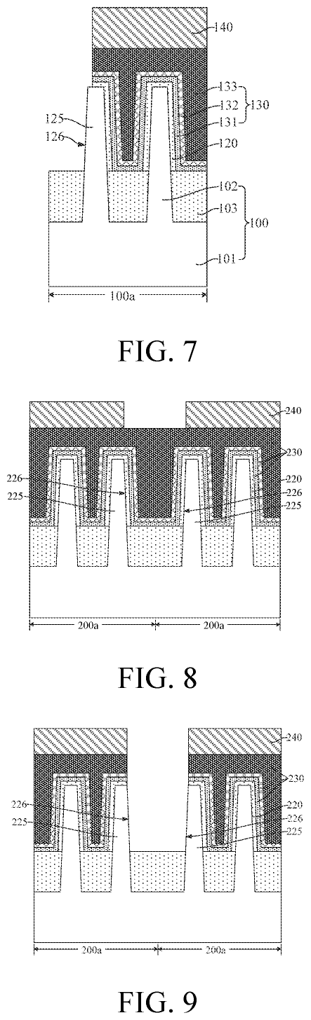

Referring to FIG. 7, in this implementation, after etching the gate structure 130, the method further includes: etching the gate oxide layer 120 exposed by the remaining gate structure 130.

In this implementation, after etching the gate structure 130 on the outer side wall 126 of any of the edge fins 125, the method further includes: removing the mask layer 140. By removing the mask layer 140, preparations are made for the subsequent process. Specifically, after the gate oxide layer 120 exposed by the remaining gate structure 130 is etched, the mask layer 140 may be removed, so that the mask layer 140 can still act as an etching mask in the process of etching the gate oxide layer 120, thereby protecting the remaining gate structure 130 or other protective layers (e.g., the interlayer dielectric layer).

In this implementation, by using the anisotropic dry etching, etching parameters corresponding to each layer are adjusted during the etching process, and the gate structure 130 and the gate oxide layer 120 are sequentially etched. This leads to high etching controllability and high morphological quality of the etch profile.

It should be noted that in other implementations, in order to save the process steps and reduce the influence on the edge fin, the gate oxide layer may not be etched. It should also be noted that after etching the gate structure 130 on the outer side wall 126 of any of the edge fins 125, the method further includes: forming a second interlayer dielectric layer (not shown) covering the edge fin 125 exposed by the remaining gate structure 130. The second interlayer dielectric layer and the first interlayer dielectric layer form an interlayer dielectric layer, thereby providing a process basis for the subsequent process. Moreover, in other implementations, when the gate structure is a dummy gate, the second interlayer dielectric layer covers the edge fin exposed by the remaining gate structure, thereby making preparation for the subsequent formation of the device gate structure and further ensuring that the device gate structure can still expose a part of the edge fin 125. Specifically, after etching the gate oxide layer 120 exposed by the remaining gate structure 130, the second interlayer dielectric layer is formed. A material of the second interlayer dielectric layer is an insulating material. As an example, the material of the second interlayer dielectric layer is silicon oxide.

FIG. 8 to FIG. 9 are schematic structural diagrams corresponding to steps of a forming method of a semiconductor structure according to another embodiment of the disclosure.

The similarities between this implementation of the disclosure and the foregoing implementations are not repeated here, and this implementation of the disclosure differs from the foregoing implementations primarily in that: in the step of providing the base (not shown), the number of the transistor cell areas 200a is plural.

In this implementation, transistors in each transistor cell area 200a share a gate structure 230, and gate structures 230 in adjacent transistor cell areas 200a are isolated. Specifically, as shown in FIG. 8, in the step of forming the gate structure 230 on the base, the gate structure 230 spans a plurality of transistor cell areas 200a, and in this case, the forming method further includes: performing gate cut on the gate structure 230 at a junction of the adjacent transistor cell areas 200a to divide the gate structure 230 of the adjacent transistor cell areas 200a in the extending direction of the gate structure 230 such that the gate structures 230 in the adjacent transistor cell areas 200a are isolated.

In this implementation, the gate structure 230 spans a plurality of transistor cell areas 200a, which increases the process window during the formation of the gate structure 230, thereby improving the quality of the formed gate structure 230. In particular, as a feature size of integrated circuits continues to decrease, when the gate structure 230 is a film stack structure (for example, when the gate structure 230 is a metal gate), the quality of the formed gate structure 230 can be improved significantly. In this implementation, the gate structure 230 is a device gate structure. Specifically, the device gate structure is a metal gate. Compared with the solution of forming the dummy gate spanning the plurality of transistor cell areas first, then performing gate cut on the dummy gate at the junction of the adjacent transistor cell areas and replacing the dummy gate with the device gate structure, in this implementation, the device gate structure is formed first, and then the device gate structure is cut off, so that the problem of difficulty in forming the device gate structure on the side wall of the opening and in the area between the adjacent fins is addressed, which is beneficial to improve the completeness of the device gate structure and increase the process window for forming the device gate structure, thereby improving the performance and performance uniformity of the transistor. Moreover, the above method has high process compatibility and low probability of producing negative influence on the performance of the transistor.

In other implementations, according to the process demands, the gate structure may also be a dummy gate.

As an example, in the transistor cell area 200a, the fin closest to the junction of the adjacent transistor cell areas 200a is used as the edge fin 225.

Referring to FIG. 9, gate cut is performed on the gate structure 230 at the junction of the adjacent transistor cell areas 200a to divide the gate structure 230 of the adjacent transistor cell areas 200a in the extending direction of the gate structure 230.

The transistors in each transistor cell area 200a share a gate structure 230. By performing gate cut on the gate structure 230 at the junction of the adjacent transistor cell areas 200a, the gate structures 230 in the transistor cell areas 200a are isolated, so that the gate structure 230 separately controls the channels in the corresponding transistor cell area 200a.

In this implementation, during the gate cut process, the gate structure 230 on the outer side wall 226 of any of the edge fins 225 is etched to remove at least a part of the gate structure 230 on the outer side wall 226. In one step, the gate structure 230 on any of the edge fins 225 is etched and gate cut is performed on the gate structure 230 at the junction of the adjacent transistor cell areas 200a, which thereby avoids introducing additional process steps; and moreover, it is possible to use one mask, which avoids additional masks. Therefore, the step of etching the gate structure 230 on any of the edge fins 225 introduced into the technical process has high compatibility with the traditional technical process and small influence on manufacturing efficiency and process cost.

Specifically, the step of etching the gate structure 230 on the outer side wall 226 of any of the edge fins 225 includes: forming a mask layer 240 on tops of the base and the gate structure 230, the mask layer 240 exposing the gate structure 230 on the outer side wall 226 of any of the edge fins 225 and the gate structure 230 at the junction of the adjacent transistor cell areas 200a; and by using the mask layer 240 as a mask, etching the gate structure 230 exposed by the mask layer 240. For the detailed description of the mask layer 240 and the process of etching the gate structure 230, reference may be made to the corresponding description in the foregoing embodiment, and details will not be repeated here.

In this implementation, the fin closest to the junction of the adjacent transistor cell areas 200a is used as the edge fin 225, so the gate structure 230 on the outer side wall 226 close to the junction of the transistor cell areas 200a is etched during the gate cut process. A mask opening is typically formed in the mask layer 240 to expose the top of the gate structure 230 to be etched. Therefore, by etching the gate structure 230 on the outer side wall 226 close to the junction of the adjacent transistor cell areas 200a, it is only required to increase a size of the mask opening at the junction of the adjacent transistor cell areas 200a in the traditional gate cut process, so as to expose the gate structure 230 to be etched on the edge fin 225. In this way, the gate structure 230 on the edge fin 225 can be etched by just slightly changing the traditional gate cut process. Accordingly, in the design of the mask, it is only required to adjust patterns and dimensions of the mask used by gate cut. In other implementations, according to the process demands, the area subjected to gate cut and the area where the gate structure on the edge fin is etched may also be isolated.

In this implementation, after etching the gate structure 230, the method may further include: etching the gate oxide layer 220 exposed by the remaining gate structure 230.

For the detailed description of the forming method of a semiconductor structure, reference may be made to the corresponding description in the foregoing implementations, as details will not be repeated here.

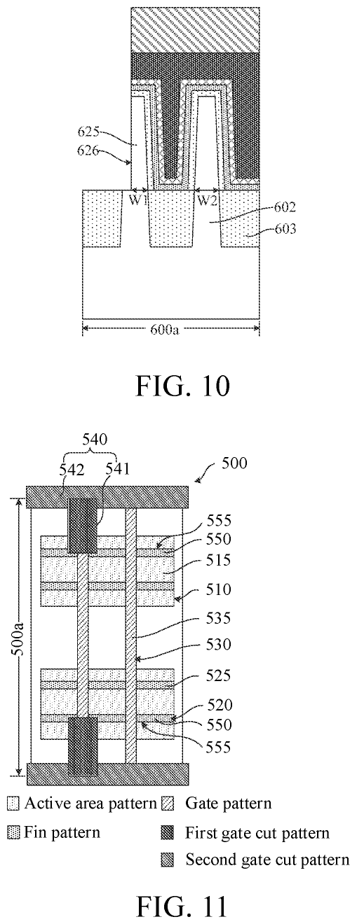

FIG. 10 is a schematic structural diagram of another form of a forming method of a semiconductor structure according to the disclosure.

The similarities between this implementation of the disclosure and the foregoing implementations are not repeated here, and this implementation of the disclosure differs from the foregoing implementations in that: after etching the gate structure on an outer side wall 626 of any of the edge fins 625, the method further includes: using a top surface of the isolation layer 603 as an etch stop position, and removing the edge fin 625 exposed by the gate structure (not shown) by etching to reduce a width of the edge fin 625.

Typically, there is an etch selectivity between the fin and the isolation layer 603, so it is easy to use the top surface of the isolation layer 603 as the etch stop position. In this implementation, after etching the gate structure on the edge fin 625 exposed by the mask layer by using the mask layer (not shown) as the mask, the gate oxide layer (not shown) and the edge fin 625 are further etched, thereby reducing the width of the edge fin 625.

In this implementation, after removing the edge fin 625 exposed by the gate structure by etching, in the transistor cell area 600a, in the direction perpendicular to the extending direction of the fin 602, on the top surface of the isolation layer 603, the edge fin 625 corresponding to the outer side wall 626 exposed by the gate structure has a first bottom width W1, and the remaining fin 602 has a second bottom width W2. The first bottom width W1 is less than the second bottom width W2.

After the gate structure on the outer side wall 626 of the edge fin 625 is etched, the gate structure does not cover a top and two opposite side walls of the edge fin 625, but exposes at least a part of the outer side wall 626. Therefore, by removing the edge fin 625 exposed by the remaining gate structure by etching, the width of the edge fin 625 is reduced, thereby improving the ability of the gate structure to control the channel in the remaining edge fin 625 and reducing the leakage current.

Specifically, by using the anisotropic dry etching, etching parameters corresponding to each layer are adjusted during the etching process, and then the gate structure 630, the gate oxide layer 620 and the edge fin 625 can be sequentially etched. This leads to high etching controllability and high morphological quality of the etch profile.

For the detailed description of the forming method of a semiconductor structure, reference may be made to the corresponding description in the foregoing implementations, as details will not be repeated here.

FIG. 11 is a schematic diagram of one form of a photomask layout according to the disclosure.

The photomask layout 500 includes: an active area layout 510, including a transistor cell area 500a for forming transistors, the transistor cell area 500a having an active area pattern 515; a fin layout 520, including a plurality of fin patterns 525 arranged in parallel in the active area pattern 515, and in a direction perpendicular to an extending direction of the fin pattern 525, the fin pattern 525 closest to a boundary of the transistor cell area 500a being used as an edge fin pattern 550, and the edge fin pattern 550 having an outer boundary 555 facing the boundary of the transistor cell area 500a; a gate layout 530, including a gate pattern 535 located in the transistor cell area 500a, the gate pattern 535 spanning the fin pattern 525 and being orthogonal to the fin pattern 525; and a gate cut layout 540, including a first gate cut pattern 541, the first gate cut pattern 541 covering the gate pattern 535 between any outer boundary 555 and the boundary of the transistor cell area 500a.

The fin pattern 525 is used for forming the fin, the edge fin pattern 550 is accordingly used for forming the edge fin, the gate pattern 535 is used for forming the gate structure, and the first gate cut pattern 541 is used for defining the etched area in the gate structure. Therefore, by adding the first gate cut pattern 541 in the photomask layout 500, when a semiconductor structure is formed by using the photomask layout 500, the gate structure on the outer side wall of any of the edge fins (i.e., the side wall of the edge fin facing the boundary of the transistor cell area) can be etched to remove at least a part of the gate structure on the outer side wall. Both a side wall and a top of the fin can be used for providing channels of the transistor, that is, both a height and a width of the fin covered by the gate structure may affect the effective channel width of the transistor. Accordingly, by etching the gate structure on the outer side wall of any of the edge fins to remove at least a part of the gate structure on the outer side wall, an area of the side wall of the edge fin covered by the gate structure is reduced, so that an effective channel width of the fin can be reduced by adjusting a height of the outer side wall exposed by the gate structure while ensuring the normal operation of the transistor, thereby improving the flexibility to adjust the effective channel width of the transistor.

The photomask layout 500 is used for preparing a mask required for the formation of the semiconductor structure. In this implementation, the description is made by taking the layout of a standard cell as an example. The layout of the standard cell is retrieved from a standard cell library. The standard cell library contains various types of standard cells that have different heights.

The standard cell library contains standard cells in the semiconductor process, and the arrangement of the standard cell typically uses a minimum design rule. The various types of standard cells have different heights to meet performance requirements of different chips. It should be noted that the height of the standard cell in the standard cell library is typically fixed, which facilitates the arrangement of the layout. In the standard cell library, the height of the standard cell is typically measured in terms of number of tracks. For example, the height of the standard cell may be 6 tracks, 6.5 tracks, 7.5 tracks or 9 tracks.

It should also be noted that for a logic circuit, an area of the active area is determined by the height of the standard cell. For example, for a fin field-effect transistor, the height of the standard cell is determined by the number of fins that can be contained in the corresponding active area, and standard cells with different heights have corresponding power consumptions and power characteristics. As an example, the 6-track standard cell is the standard cell with the smallest height in the standard cell library.

In other implementations, the photomask layout may also be a layout after the completion of the arrangement design.

It should be noted that the transistors formed in the same transistor cell area 500a share a gate structure, but each transistor cell area 500a is not limited to forming transistors of the same channel conductivity type. For example, one transistor cell area 500a can be used for forming an NMOS transistor and a PMOS transistor, i.e., one transistor cell area 500a can be used for forming a plurality of transistors, and the NMOS transistor and the PMOS transistor share a gate structure. In other implementations, according to the circuit design, each transistor cell area is used for forming transistors of the same channel conductivity type, and each transistor cell area is used for forming only one transistor.

It should also be noted that each transistor cell area 500a has boundaries in all directions.

The active area layout 510 includes a plurality of active area patterns 515, and the active area patterns 515 are used for forming areas on a wafer where active devices are formed. In the direction perpendicular to the extending direction of the fin pattern 525, each active area pattern 515 is used for defining a formation position of one type of transistors.

In this implementation, the number of the fin patterns 525 in each active area pattern 515 is two.

The fin patterns 525 are used for forming fins, and the fins are used for providing channels of the transistor. Specifically, when the gate structure covers the fin, a channel width that can be provided by the fin is the sum of a width of the fin and twice an effective height of the fin. Therefore, the larger the number of fins corresponding to the transistor, the larger the channel width of the transistor.

Each transistor cell area 500a has boundaries in all directions, and in the direction perpendicular to the extending direction of the fin pattern 525, the fin pattern 525 closest to the boundary of the transistor cell area 500a is used as the edge fin pattern 550, and the edge fin pattern 550 has the outer boundary 555 facing the boundary of the transistor cell area 500a.

The gate pattern 535 is used for forming a gate structure. In the semiconductor process, the gate structure spans the fin and covers a part of the top and a part of the side wall of the fin, so the gate pattern 535 spans the fin pattern 525 in the active area pattern 515 and is orthogonal to the fin pattern 525 in the active area pattern 515.

In this implementation, the transistor cell area 500a includes a plurality of active area patterns 515, and transistors formed in the same transistor cell area 500a share a gate structure. Therefore, in the transistor cell area 500a, the gate pattern 535 spans the plurality of active area patterns 515 and is orthogonal to the fin patterns 525 in the plurality of active area patterns 515, and the plurality of active area patterns 515 share a gate pattern 535.

The first gate cut pattern 541 covers the gate pattern 535 between any outer boundary 555 and the boundary of the transistor cell area 500a. The first gate cut pattern 541 is used for defining an etch position of the gate structure corresponding to the gate pattern 535, so that the gate structure in the target area can be removed by etching in the semiconductor manufacturing process. Therefore, when the semiconductor structure is formed using the photomask layout 500, the gate structure on the outer side wall of any of the edge fins can be etched to remove at least a part of the gate structure on the outer side wall, so that the area of the side wall of the edge fin covered by the gate structure is reduced. Thereby, the effective channel width of the fin can be reduced by adjusting the height of the outer side wall exposed by the gate structure while ensuring the normal operation of the transistor, thereby improving the flexibility to adjust the effective channel width of the transistor.

It should be noted that in the semiconductor manufacturing process, when the gate structure in the area corresponding to the first gate cut pattern 541 is etched by using the mask prepared based on the gate cut layout 540, the exposed area of the gate structure can be adjusted by adjusting the parameters of the photo-lithography process, thereby controlling the area of the gate structure to be etched. For example, a part of the gate structure on the outer side wall may be removed; or the gate structure on the entire outer side wall is removed; or the gate structure on the entire outer side wall is removed, and a part of the gate structure on the top of the edge fin is also removed; or the gate structure on the entire outer side wall is removed, and the gate structure on the top of the edge fin is also removed.

It should also be noted that FIG. 11 only shows one transistor cell area 500a, and in an actual photomask layout 500, in the active area layout 510, the number of the transistor cell areas 500a may be plural. Since each transistor cell area 500a has the boundaries in all directions, when the number of the transistor cell areas 500a is plural, the adjacent transistor cell areas 500a have a junction, which is the boundary of the transistor cell area 500a.

As an example, when the number of the transistor cell areas 500a is plural, in the gate layout 530, the gate pattern 535 spans a plurality of transistor cell areas 500a and is orthogonal to the fin patterns 525 in the plurality of transistor cell areas 500a. Accordingly, in this implementation, the gate layout 530 further includes a second gate cut pattern 542, and the second gate cut pattern 542 covers the gate pattern 535 at the junction of the adjacent transistor cell areas 500a. In the semiconductor manufacturing process, the second gate cut pattern 542 is used for dividing the gate structure of the adjacent transistor cell areas 500a in the extending direction of the gate structure.

In this implementation, the first gate cut pattern 541 and the second gate cut pattern 542 are located in the same gate cut layout 540, so after the first gate cut pattern 541 is added to the photomask layout, additional masks can still be avoided. In other implementations, according to the actual design requirements, the gate cut layout may also include a first sub-gate cut layout and a second sub-gate cut layout located on different layers. The first gate cut pattern is located in the first sub-gate cut layout, and the second gate cut pattern is located in the second sub-gate cut layout. That is, the first gate cut pattern and the second gate cut pattern are arranged in different masks.

Although the disclosure has been disclosed above, the disclosure is not limited thereto. Any person skilled in the art can make various changes and modifications without departing from the spirit and scope of the disclosure, so the scope of protection of the disclosure shall be subject to the scope defined by the claims.

What is claimed is:

1. A semiconductor structure, comprising:
a base, comprising a substrate and a plurality of fins arranged in parallel on the substrate, the substrate comprising a transistor cell area for forming transistors, and in the transistor cell area, in a direction perpendicular to an extending direction of the fins of the plurality of fins, a fin of the plurality of fins closest to a boundary of the transistor cell area is used as an edge fin, and the edge fin having an outer side wall facing the boundary of the transistor cell area; and
a gate structure, located on the base and spanning the fins of the plurality of fins, the gate structure covering a part of a top and a part of a side wall of the fins of the plurality of fins, and the gate structure exposing at least a part of an outer side wall the edge fin.

2. The semiconductor structure according to claim 1, wherein:
the gate structure exposes a part of the outer side wall of the edge fin; or
the gate structure exposes an entire outer side wall of the edge fin; or
the gate structure exposes the entire outer side wall of the edge fin and also exposes a part of a top of the edge fin; or
the gate structure exposes the entire outer side wall of the edge fin and also exposes the top of the edge fin.

3. The semiconductor structure according to claim 1, wherein:
the substrate comprises a plurality of transistor cell areas;
in each transistor cell area of the plurality of transistor cell areas, a fin of the plurality of finds closest to a junction of adjacent transistor cell areas of the plurality of transistor cell areas is used as the edge fin; and
portions of the gate structure in the adjacent transistor cell areas of the plurality of transistor cell areas are isolated.

4. The semiconductor structure according to claim 1, wherein:
the base further comprises: an isolation layer, located on a portion of the substrate exposed by fins of the plurality of fins, the isolation layer covering a part of the side wall of fins of the plurality of fins; and
in the transistor cell areas of the plurality of transistor cell areas, in a direction perpendicular to the extending direction of the plurality of fins, the edge fin corresponding to an outer side wall exposed by the gate structure has a first bottom width on a top surface of the isolation layer, and the remaining fins of the plurality of fins have a second bottom width on the top surface of the isolation layer, the first bottom width being less than the second bottom width.

5. The semiconductor structure according to claim 1, wherein the gate structure is a device gate structure, and the device gate structure comprises a metal gate.

6. The semiconductor structure according to claim 1, wherein the gate structure is a device gate structure, and the device gate structure comprises a gate dielectric layer and a gate layer covering the gate dielectric layer.

7. The semiconductor structure according to claim 1, wherein the semiconductor structure further comprises:
a gate oxide layer, the gate oxide layer being located between the gate structure and a fin of the plurality of fins, or the gate oxide layer located between the gate structure and a fin of the plurality of finds and also extending to cover an outer side wall exposed by the gate structure.

8. The semiconductor structure according to claim 7, wherein a material of the gate oxide layer comprises at least one of silicon oxide or silicon oxynitride.

9. The semiconductor structure according to claim 1, wherein in a direction perpendicular to the extending direction of the fins of the plurality of fins, a top width of the fins of the plurality of fins is greater than a bottom width of the fins of the plurality of fins.

10. The semiconductor structure according to claim 6, wherein a material of the gate dielectric layer comprises HfO₂, ZrO₂, HfSiO, HfSiON, HfTaO, HfSiO, HfZrO or Al₂O₃.

11. The semiconductor structure according to claim 6, wherein a material of the gate layer comprises at least one of TiN, TaN, Ta, Ti, TiAl, W, Al, TiSiN or TiAlC.

12. A forming method of a semiconductor structure, comprising:
providing a base, comprising a substrate and a plurality of fins arranged in parallel on the substrate, the substrate comprising a transistor cell area for forming transistors, and in the transistor cell area, in a direction perpendicular to an extending direction of the fins of the plurality of fins, a fin closest to a boundary of the transistor cell area is used as an edge fin, and the edge fin having an outer side wall facing the boundary of the transistor cell area;
forming a gate structure spanning the plurality of fins on the base, the gate structure covering a part of a top and a part of a side wall of the fins of the plurality of fins; and
etching the gate structure on an outer side wall of the edge fin to remove at least a part of the gate structure on the outer side wall.

13. The forming method of a semiconductor structure according to claim 12, wherein in the step of etching the gate structure on an outer side wall of the edge fin:
a part of the gate structure on the outer side wall is removed; or
the gate structure on the entire outer side wall is removed; or
the gate structure on the entire outer side wall is removed, and a part of the gate structure on a top of the edge fin is also removed; or
the gate structure on the entire outer side wall is removed, and the gate structure on the top of the edge fin is also removed.

14. The forming method of a semiconductor structure according to claim 12, wherein in the step of forming the gate structure spanning the plurality of fins on the base, the gate structure comprises a dummy gate or a device gate structure.

15. The forming method of a semiconductor structure according to claim 14, wherein the dummy gate comprises a polysilicon gate structure and an amorphous silicon gate structure, and the device gate structure comprises a metal gate.

16. The forming method of a semiconductor structure according to claim 12, wherein:
the base comprises a plurality of transistor cell areas;
in the step of forming a gate structure spanning the plurality of fins on the base, the gate structure spans the plurality of transistor cell areas; and
the forming method further comprises: performing gate cut on the gate structure at a junction of adjacent transistor cell areas of the plurality of transistor cell areas to divide the gate structure of the adjacent transistor cell areas in the extending direction of the gate structure, wherein during the gate cut process, the gate structure on the outer side wall of any of the edge fins is etched.

17. The forming method of a semiconductor structure according to claim 16, wherein:
in the transistor cell areas of the plurality of transistor cell areas, a fin of the plurality of fins closest to the junction of the adjacent transistor cell areas is used as the edge fin; and
during the gate cut process, the gate structure on the outer side wall close to the junction of the adjacent transistor cell areas is etched.

18. The forming method of a semiconductor structure according to claim 12, wherein:
the base further comprises: an isolation layer, located on the substrate exposed by the plurality of fins, the isolation layer covering a part of the side wall of fins of the plurality of fins; and
after etching the gate structure on an outer side wall of the edge fin, the method further comprises:
using a top surface of the isolation layer as an etch stop position, and
removing the edge fin exposed by the gate structure by etching to reduce a width of the edge fin.

19. The forming method of a semiconductor structure according to claim 12, wherein:
the step of etching the gate structure on an outer side wall of the edge fins comprises:
forming a mask layer on tops of the base and the gate structure, the mask layer exposing the gate structure on the outer side wall of the edge fins; and
using the mask layer as a mask, etching the gate structure exposed by the mask layer; and
the forming method further comprises: removing the mask layer.

20. The forming method of a semiconductor structure according to claim 12, wherein:
before forming the gate structure, the method further comprises: forming a gate oxide layer on the top and the side wall of the fins of the plurality of fins;
in the step of forming the gate structure, the gate structure covers the gate oxide layer; and
in the step of etching the gate structure on an outer side wall of the edge fins, the gate oxide layer is used as an etch stop layer.

21. The forming method of a semiconductor structure according to claim 12, wherein the gate structure on the outer side wall of the edge fin is etched by anisotropic dry etching.

22. The forming method of a semiconductor structure according to claim 12, wherein in the step of providing a base, in the direction perpendicular to the extending direction of the plurality of fins, a top width of a fin of the plurality of finds is greater than a bottom width of the fin of the plurality of fins.

23. A photomask layout, comprising:
an active area layout, comprising a transistor cell area for forming transistors, the transistor cell area having an active area pattern;
a fin layout, comprising a plurality of fin patterns arranged in parallel in the active area pattern, and in a direction perpendicular to an extending direction of the fin patterns, the fin pattern closest to a boundary of the transistor cell area being used as an edge fin pattern, and the edge fin pattern having an outer boundary facing the boundary of the transistor cell area;
a gate layout, comprising a gate pattern located in the cell area, the gate pattern spanning the fin pattern and being orthogonal to the fin pattern; and
a gate cut layout, comprising a first gate cut pattern, the first gate cut pattern covering the gate pattern between any outer boundary and the boundary of the transistor cell area.

24. The photomask layout according to claim 23, wherein:
in the active area layout, a number of the transistor cell areas is plural; in the gate layout, the gate pattern spans a plurality of transistor cell areas and is orthogonal to the fin patterns in the plurality of transistor cell areas; and
the gate layout further comprises a second gate cut pattern, the second gate cut pattern covering the gate pattern at a junction of the adjacent transistor cell areas.
